(19) United States
(12) Patent Application Publication
(10) Pub. No.: US 2026/0322415 A1
(43) Pub. Date: Oct. 15, 2026

(54) Methods and Apparatuses for Performing Digital Predistortion of a Plurality of Multi-Carrier Branch Signals

(71) Applicant: Telefonaktiebolaget LM Ericsson (publ), Stockholm (SE)

(72) Inventors: Simone Grimaldi, Staffanstorp (SE); Mohamed Hamid, Malmö (SE); Martin Isberg, Lund (SE); Jessica Chani, Göteborg (SE); Per Landin, Kumla (SE); Shoaib Amin, Kumla (SE)

(21) Appl. No.: 19/484,408

(22) PCT Filed: May 17, 2023
(86) PCT No.: PCT/EP2023/063257

§ 371 Date: Nov. 14, 2025

(51) Int. Cl. H04B 1/04

(52) U.S. Cl. CPC H04B 1/0475

(57) ABSTRACT

Embodiments described herein relate to a method and apparatus for performing digital predistortion of a plurality of input multi-carrier branch, MCB, signals (u₁ to u_{N}) to generate output MCB signals (x_{UP,1} to x_{UP,N}) for driving a power amplifier, wherein each input MCB signal occupies a respective initial frequency band. A method comprises obtaining an indication of a set of first frequencies (F_{C,1} to F_{C,N}) comprising central frequencies of the plurality of initial frequency bands; determining a set of second frequencies (F_{L,1} to F_{L,N}), wherein each second frequency F_{L} equals a respective first integer value (m₁ to m_{N}) multiplied by a frequency interval (Δf), wherein the frequency interval equals a highest second frequency (F_{L,N}) in the set of second frequencies divided by a second integer value, R; for each input MCB signal, u_{M}: frequency shifting the input MCB signal, u_{M} into a linearization frequency band centered on a respective second frequency F_{L,M} to generate an adjusted input MCB signal u′_{M}; performing digital predistortion on the adjusted input MCB signal, u′_{M} to generate a pre-distorted MCB signal, x_{M}; and upconverting the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

### TECHNICAL FIELD

Embodiments described herein relate to methods and apparatuses for performing DPD on a plurality of input multi-carrier branch, MCB, signals to generate output MCB signals for driving a power amplifier.

### BACKGROUND

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

The power consumption in a radio frequency (RF) amplification stage is a primary concern in the deployment of radio base stations. The power amplifiers (PAs) in this stage are often driven with significant input power to secure satisfactory efficiency. One drawback is that the PA units might exhibit significant nonlinear behavior, depending on the employed PA technology.

Nonlinearity of the PA stage results in a degradation of the quality of the emitted signal, which hinders not only the achievable modulation schemes, but also creates unwanted emissions within the adjacent channels and outside the operating band due to spectral regrowth. The above characteristics are severely regulated by 3GPP specifications (see for example, ETSI, “3GPP TS 38.104 version 15.14.0 Release 15,” 2021.) in terms of adjacent channel leakage ratio (ACLR) and error vector magnitude (EVM), which is modulation-type dependent.

A widely adopted approach for mitigating the effects of a PA's nonlinearity is to pre-process the signal in the digital domain by means of a digital pre-distortion (DPD) process. The approach has countless variants and has its foundations in the idea of compensating for the nonlinear behavior by determining and applying the inverse nonlinear transformation to the PA input signal. While DPD may be used to linearize both single-band and multiband signals, applying the technique directly in the latter case (i.e., using a single DPD for linearizing a multiband signal) may lead to extreme requirements on the sample rate of the DPD.

An alternative approach for decreasing bandwidth requirements in multiband linearization is to adopt a separate DPD (S-DPD) for each signal band, for example as illustrated in FIG. 1.

FIG. 1 illustrates a system 100 comprising a plurality of separate digital pre-distorters (S-DPDs) 101a to 101c receiving separate multi-carrier branch (MCB) digital signals uᵢ[n] in a scenario in which 3 separate branches are transmitted to the same PA 102.

With S-DPDs, signals that occupy a specific bandwidth—known as linearization bandwidth—are linearized, while distortions in other frequency regions across the operating band of the PA are mitigated via analog filtering.

While the S-DPD architecture allows for the operation of predistortion at lower sample rates, it also demands multi-variate models for the S-DPD blocks to counteract intermodulation effects.

Such effects are due to the nonlinear response of the PA to a multiband input, which produces intermodulation terms (IMs) located within frequency bands to be linearized.

Furthermore, the frequency locations of IMs vary according to the location of the carrier frequencies, while the bandwidths of the IMs are a function of the bandwidths of the original carriers. The phenomenon of IMs limits the validity and generalizability of S-DPD models as different bands and carrier configurations result in a diverse distortion footprint in the frequency domain.

In concurrent multiband transmission, the PA nonlinearity introduces IMs that might be off-centered with different carriers in different bands. To linearize such IMs the physical model used in the DPD may need to consider the locations of those IMs individually, which implies a significant increase in complexity (see, for example, Cao, S. Wang and T. Eriksson, “Concurrent multiband linearization for power amplifiers with intermodulation distortions,” IEEE Microwave and Wireless Components Letters, vol. 32, no. 5, pp. 467-470, 2022).

In practice, each S-DPD is required to generate the appropriate basis functions of the pre-distorted signal to compensate for each IM. The generation of basis functions related to off-centered IMs implies estimating the baseband frequencies of the basis functions and performing distinct frequency-shifting operations. The complexity of this task escalates with the number of concurrent bands and the nonlinearity order considered in the DPD model. Furthermore, currently available solutions in the literature focus on linearization processes specialized on a particular multiband configuration e.g., dual- or tri-band, which limits their applicability in the context of an increased number of bands or different band placement.

Some efforts in the literature have been made to address the specific problem of the minimization of frequency-shifts and obtaining a better generalization for the S-DPD model.

In G. Su and W. Chen, “Digital predistortion for concurrent multi-band PAs with inter-band IMD compensation,” in IEEE International Workshop on Electromagnetics, Nanjing, China, 2016, the authors have shown that a carrier frequency setting that follows an evenly-spaced frequency distribution is beneficial in terms of reducing the number of off-centered IMs, therefore having simpler S-DPD models. However, this solution may not be applicable in practical scenarios, as the carrier frequency planning within the licensed bands is controlled by mobile operators.

In W. Cao, et al., the authors propose a frequency shift at the input of the S-DPD to place the carriers in an equidistant configuration to enable simpler S-DPD models, and then to operate an a-posteriori frequency shift to re-center the carriers in the correct position.

### SUMMARY

According to some embodiments there is provided a method for performing digital predistortion of a plurality of input multi-carrier branch, MCB, signals, u₁ to u_{N}, to generate output MCB signals, x_{UP,1} to x_{UP,N}, for driving a power amplifier, wherein each input MCB signal occupies a respective initial frequency band. The method comprises obtaining an indication of a set of first frequencies, F_{C,1} to F_{C,N}, comprising central frequencies of the plurality of initial frequency bands; determining a set of second frequencies, F_{L,1} to F_{L,N}, wherein each second frequency F_{L} equals a respective first integer value, m₁ to m_{N}, multiplied by a frequency interval, Δf, wherein the frequency interval equals a highest second frequency, F_{L,N}, in the set of second frequencies divided by a second integer value, R; for each input MCB signal, u_{M}: frequency shifting the input MCB signal, u_{M} into a linearization frequency band centered on a respective second frequency F_{L,M} to generate an adjusted input MCB signal u′_{M}; performing digital predistortion on the adjusted input MCB signal, u′_{M} to generate a pre-distorted MCB signal, x_{M}; and upconverting the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

According to some embodiments there is provided an apparatus for performing digital predistortion of a plurality of input multi-carrier branch, MCB, signals (u₁ to u_{N}) to generate output MCB signals, x_{UP,1} to x_{UP,N}, for driving a power amplifier, the apparatus comprising processing circuitry configured to cause the apparatus to: obtain an indication of a set of first frequencies, F_{C,1} to F_{C,N}, comprising central frequencies of the plurality of initial frequency bands; determine a set of second frequencies, F_{L,1} to F_{L,N}, wherein each second frequency F_{L} equals a respective first integer value, m₁ to M_{N}, multiplied by a frequency interval, Δf, wherein the frequency interval equals a highest second frequency, F_{L,N}, in the set of second frequencies divided by a second integer value, R; for each input MCB signal, u_{M}: frequency shift the input MCB signal, u_{M} into a linearization frequency band centered on a respective second frequency F_{L,M} to generate an adjusted input MCB signal u′_{M}; perform digital predistortion on the adjusted input MCB signal, u′_{M} to generate a pre-distorted MCB signal, x_{M}; and upconvert the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

### BRIEF DESCRIPTION OF THE DRAWINGS

For a better understanding of the embodiments of the present disclosure, and to show how it may be put into effect, reference will now be made, by way of example only, to the accompanying drawings, in which:

FIG. 1 illustrates a system in which a plurality of separate digital pre-distorters (S-DPDs) receive separate multi-carrier branch (MCB) digital signals in a scenario in which three separate branches are transmitted to a power amplifier;

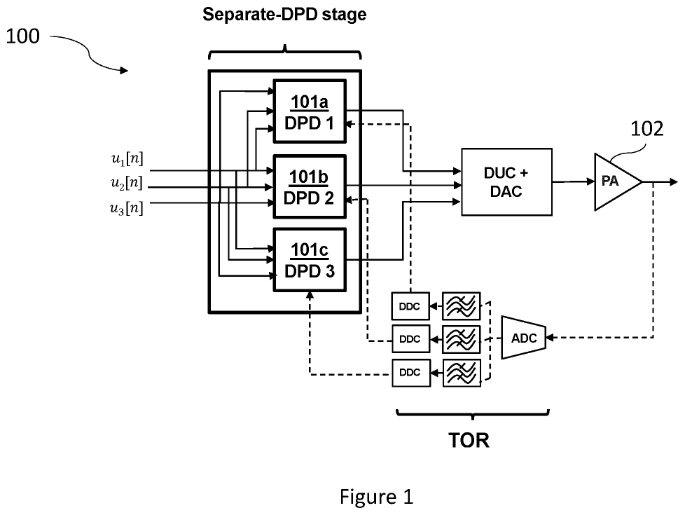

FIG. 2 illustrates a method of performing digital predistortion of a plurality of input multi-carrier branch, MCB, signals to generate output MCB signals for driving a power amplifier FIG. 3 illustrates an example of the input MCB signals occupying the respective initial frequency bands;

FIG. 4 illustrated graphs showing the optimisation of the second integer value R;

FIG. 5 illustrates an example of the plurality of linearization frequency bands for the initial frequency bands and carrier frequencies illustrated in FIG. 3;

FIG. 6 illustrates a DPD system according to some embodiments;

FIG. 7 illustrates an example implementation of a linearization bands configuration block according to some embodiments;

FIG. 8 illustrates an example implementation of the optimiser block;

FIG. 9 illustrates the spectrum of signals with and without S-DPD for the standard linearization bands (SLB) case;

FIG. 10 illustrates the spectrum of signals with and without S-DPD for the proposed solution;

FIG. 11 illustrates the complexity of S-DPD in terms of NCO, number of frequency shifts and complex multiplications (CM) related to the additional frequency shifts in different scenarios: standard linearization bands (SLB), and the proposed solution;

FIG. 12 illustrates an apparatus comprising processing circuitry (or logic);

FIG. 13 is a block diagram illustrating an apparatus according to some embodiments.

### DESCRIPTION

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail. Those skilled in the art will appreciate that the functions described may be implemented in one or more nodes using hardware circuitry (e.g., analog and/or discrete logic gates interconnected to perform a specialized function, ASICs, PLAs, etc.) and/or using software programs and data in conjunction with one or more digital microprocessors or general purpose computers. Nodes that communicate using the air interface also have suitable radio communications circuitry. Moreover, where appropriate the technology can additionally be considered to be embodied entirely within any form of computer-readable memory, such as solid-state memory, magnetic disk, or optical disk containing an appropriate set of computer instructions that would cause a processor to carry out the techniques described herein.

Hardware implementation may include or encompass, without limitation, digital signal processor (DSP) hardware, a reduced instruction set processor, hardware (e.g., digital or analog) circuitry including but not limited to application specific integrated circuit(s) (ASIC) and/or field programmable gate array(s) (FPGA(s)), and (where appropriate) state machines capable of performing such functions.

Certain aspects of the present disclosure and their embodiments may provide solutions to these or other challenges. The steps of any methods disclosed herein do not have to be performed in the exact order disclosed, unless a step is explicitly described as following or preceding another step and/or where it is implicit that a step must follow or precede another step.

Particular embodiments are described more fully with reference to the accompanying drawings. Other embodiments, however, are contained within the scope of the subject matter disclosed herein. The disclosed subject matter should not be construed as limited to only the embodiments set forth herein; rather, these embodiments are provided by way of example to convey the scope of the subject matter to those skilled in the art.

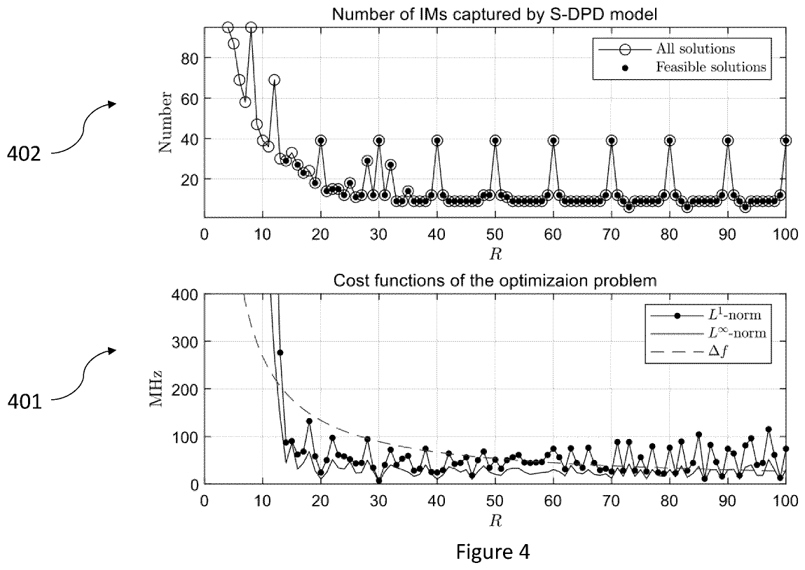

Aspects and examples of the present disclosure thus overcome some of the limitations of the disclosure of W. Cao, S. Wang and T. Eriksson, “Concurrent multiband linearization for power amplifiers with intermodulation distortions,” IEEE Microwave and Wireless Components Letters, vol. 32, no. 5, pp. 467-470, 2022 (reference 1), for example:
1. The solution in reference 1 requires a bank of N-frequency shifters (with N number of concurrent carriers) to off-center the input to the predistorted signal and a bank of N-frequency shifters to re-center the predistorted signals. Embodiments described herein only require that the shift is compensated during the generation of the multiband signal via a frequency offset, therefore eliminating the need for an additional block.
2. The solution presented in reference 1 operates the preliminary frequency shifts through a set of N frequency shifters while the proposed solution allows to upper bound this number to M−1 (where M is the number of S-DPDs), and in some cases reduce it to one unit (e.g., see the exemplary tri-band case illustrated in FIGS. 3 and 5 herein) leading to a simpler architecture in terms of frequency shifter units and number of required operations.
3. The solution in reference 1 uses a fixed scheme for frequency selection for programming the bank of frequency shifters. The embodiments described herein instead include a framework for determining the value according to the minimization of a certain objective function, e.g., number of frequency shifter units, or magnitude of the shifts. This has greater flexibility and can be used to reduce the number of required complex multiplications due to the shifts.
4. The applicability of the solution to the case of more than one carrier transmitted on each band is not addressed in reference 1. The embodiments described herein instead work also in the case of more than one carrier per band, as the shift is only related to the central frequency of the baseband signal and not to the specific carrier.

Embodiments described herein provide a method to reduce model and process complexity of multiband linearization via separate-DPD (S-DPDs). The complexity reduction is enabled through alternative representation of S-DPDs' input signals. Such an alternative representation is achieved via a linearization bands shift to achieve a proposed placement of linearization bands. Accordingly, the number of frequency shifts scales with the number of bands instead of the number of off-centered IMs.

In one embodiment, a minimization of the number of frequency shifts is achieved by L⁰ norm minimization. In a second embodiment the accumulation of frequency shift is minimized by L¹ norm minimization and in a third embodiment the maximum frequency shift applied to baseband signals is minimized using L∞ norm minimization.

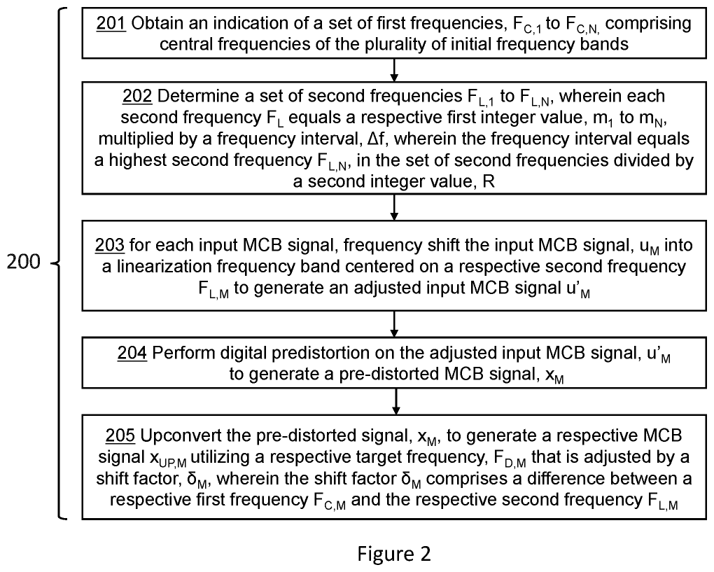

FIG. 2 illustrates a method of performing digital predistortion of a plurality of input multi-carrier branch, MCB, signals (u₁ to u_{N}) to generate output MCB signals (x_{UP,1} to x_{UP,N}) for driving a power amplifier, wherein each input MCB signal occupies a respective initial frequency band.

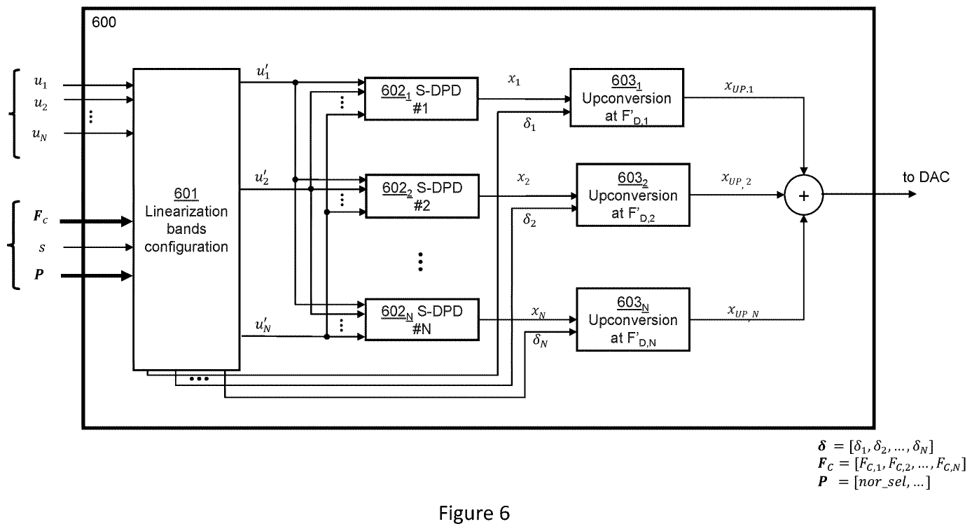

The method 200 may be performed by a network node, which may comprise a physical or virtual node, and may be implemented in a computing device or server apparatus and/or in a virtualized environment, for example in a cloud, edge cloud or fog deployment. In particular the method may be performed by a system 600 as described later with reference to FIGS. 6 to 8. The system 600 may be comprised in a base station in a radio access network.

FIG. 3 illustrates an example of the input MCB signals occupying the respective initial frequency bands 301₁ to 301₄. The initial frequency bands 301₁ to 301₄ are entered at on a set of first frequencies F_{C,1} to F_{C,4}.

In step 201 the method comprises obtaining an indication of a set of first frequencies (F_{C,1} to F_{C,N}) comprising central frequencies of the plurality of initial frequency bands. In the example illustrated in FIG. 3 the set of first frequencies F_{C,1} to F_{C,4} are indicated.

In step 202, the method comprises determining a set of second frequencies (F_{L,1} to F_{L,N}), wherein each second frequency F_{L} equals a respective first integer value (m₁ to M_{N}) multiplied by a frequency interval (Δf), wherein the frequency interval equals a highest second frequency (F_{L,N}) in the set of second frequencies divided by a second integer value, R.

In other words, the set of second frequencies may be selected as F_{L,i} (with i∈[1,N]) such that:

F_{L,i}=Δf−mᵢ (Equation 1)
with m₁>m₂> . . . >m_{N}_{_{L}} positive integers, and the spacing Δf verifying

$$Δ f = \frac{{F}_{L , N}}{R} . \qquad ( Equation 2 )$$

A shift vector δ, may then be defined that comprises a difference between a vector of the first set of frequencies, F_{C} and a vector of the second set of frequencies, F_{L}.

In other words, δ=F_{C}−F_{L}.

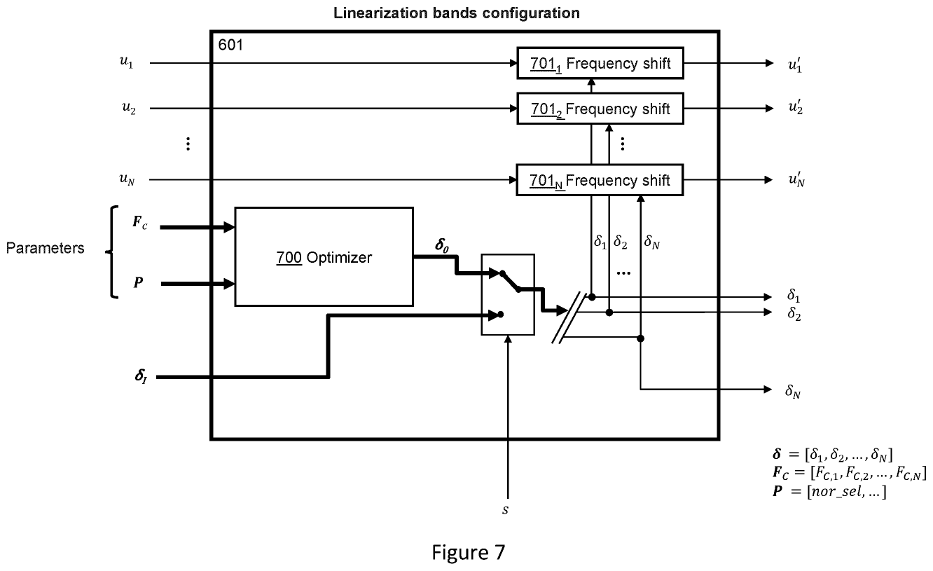

As will be described later with reference to FIG. 7, in some examples the shift vector may be defined by a user in a manual mode of operation. However, in some examples, the shift vector is determined automatically in an automatic mode of operation.

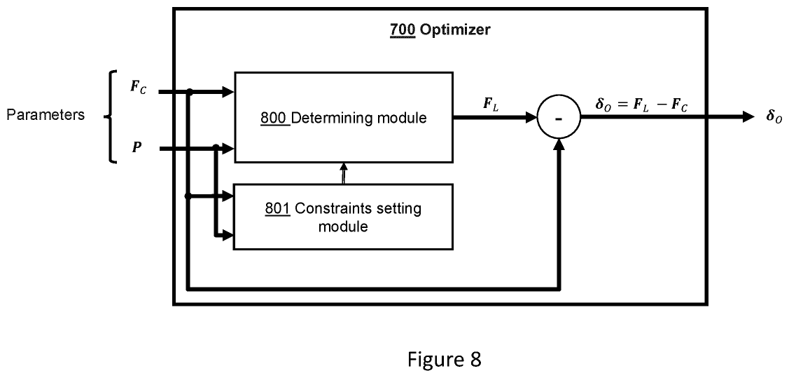

Step 202 may comprise selecting the second set of frequencies to reduce an L^{nor_sel} norm of the shift vector. For example, step 202 may comprise selecting one or more of the respective first integer values (mᵢ) and the second integer value (R) to reduce an L^{nor_sel} norm of the shift vector. As will be described in more detail with reference to FIG. 8 the value of nor_sel for the L^{nor_sel} norm may be received by the system as an input. The parameter nor_sel, which may be received via a set of parameters P, may be an arbitrarily selected integer number between [0, ∞] defining the norm (e.g. L^{nor_sel}) to be used in the minimization problem, and this norm may be solved via any suitable optimization method.

In some examples, step 202 may additionally or alternatively comprise selecting one or more of: the respective first integer values and the second integer value to ensure a number of intermodulation terms located at hypothetical carrier frequencies should the hypothetical carrier frequencies be set equal to the set of second frequencies reaches or surpasses a threshold number of intermodulation terms. For example, step 202 may comprise maximizing the number of number of intermodulation terms located at the hypothetical carrier frequencies should the hypothetical carrier frequencies be set equal to the set of second frequencies.

In other words, consider an alternative (hypothetical) carrier configuration where the new carrier frequencies F′_{C}=[F′_{C,1}, F′_{C,2}, . . . , F′_{C,N}] are selected to match the set of second frequencies.

In other words, F′_{C}=F_{L}=[F_{L,1}, F_{L,2}, . . . , F_{L,N}].

The frequencies of single IM terms (monomials) that would originate from intermodulation of the carrier frequencies in F′_{C} up to an arbitrary order of nonlinearity may then be calculated. Calculating such frequencies is straightforward and well-known in nonlinear systems theory (see for example, G. Su and W. Chen, “Digital predistortion for concurrent multi-band PAs with inter-band IMD compensation,” 2016 IEEE International Workshop on Electromagnetics: Applications and Student Innovation Competition (iWEM), Nanjing, China, 2016, pp. 1-3, doi: 10.1109/iWEM.2016.7504909).

A set of IM monomial frequencies may then be determined as:

F_{IM}=[F_{IM,1},F_{IM,2}, . . . , F_{IM,K}]

F_{IM} may then be used to determine a number of IM monomials having frequencies equal to the new (hypothetical) carrier frequencies. It will be appreciated that the order of the intermodulation terms may be arbitrary.

In other words, how many of F_{IM,n}∈F′_{C}. This may then be referred the amount of IMs captured by S-DPD model.

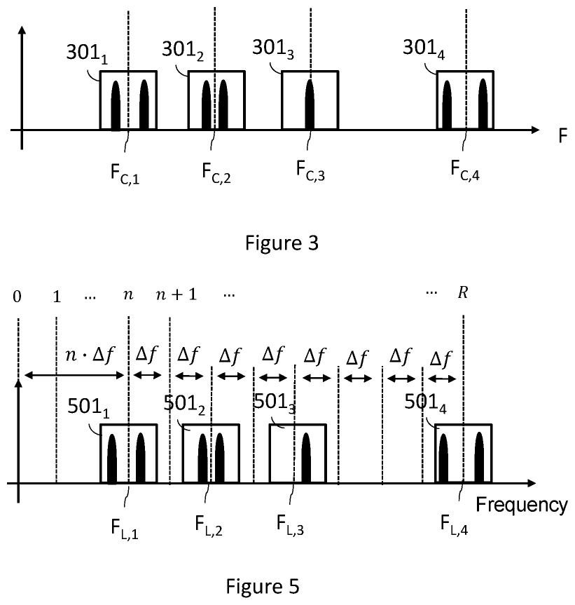

At this point the maximization of the amount of IMs captured by the S-DPD model may proceed according to any arbitrary optimization process. For example, a grid-search approach over the first integer values (m₁ to M_{N}) may be utilized. This maximization may be performed by evaluating the amount of IM terms for different solutions of the optimization problem related to a specific setting of the second integer value R (for example as described with reference to FIG. 4 below).

Maximizing the number of IMs captured by the S-DPD model will increase the linearization performance of the S-DPDs.

Irrespective of the method to perform optimization, the optimization may be configured to increase an amount of IMs captured by the S-DPD model and reduce an L-norm for the shift vector.

An example of the optimization is illustrated in FIG. 4.

In this example, which covers a triband case, R=20 is selected since it ensures a low value for the target cost functions (L-1 and L-∞, shown in the graph 401) and a high number of IM terms captured by the S-DPD models (graph 402). It should be noted that any selection of R in these graphs would provide a configuration according to embodiments described herein, and that the selection of a specific value is arbitrary and functional to optimize:
Linearization performance—in other words to increase or maximize a number of IMs captured by the S-DPD model.
A Magnitude and/or number of frequency shifts—in other words to decrease or minimize a cost function carrying information on the required frequency shift (e.g., an L⁰-norm (minimize number of frequency shifts), L1-norm (minimize cumulative shift), or L-∞ norm (minimize maximum shift)).

Therefore, an arbitrary multi-objective optimization method (Pareto optimization) or heuristic approach can be used in this context to determine the value of R and the related first integer values (m₁ to M_{N}).

In step 203 the method comprises, for each input MCB signal, u_{M} frequency shifting the input MCB signal, u_{M} into a linearization frequency band centered on a respective second frequency F_{L,M} to generate an adjusted input MCB signal u′_{M};

FIG. 5 illustrates an example of the plurality of linearization frequency bands 501₁ to 501₄ for the initial frequency bands and carrier frequencies illustrated in FIG. 3.

In other words, for the input signal u₁ is frequency shifted into the linearization band 501₁ centered on F_{L,1} to generate an adjusted input MCB signal, u′₁.

In step 204 the method comprises performing digital predistortion on the adjusted input MCB signal, u′_{M} to generate a pre-distorted MCB signal, x_{M}.

As will be illustrated later step 204 may be performed in separate DPD blocks for each input MCB signal.

In step 205 the method comprises upconverting the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

For example, step 205 may comprise calculating the output MCB signal x_{UP,M} as: x_{UP,M}=x_{M}e^{j2π(f}^{_{C,M}}^{-δ}^{_{M}}^{)t}.

For example, x_{UP,1}=x₁e^{j2π(f}^{_{C,1}}^{-δ}^{₁}^{)t}.

FIG. 6 illustrates a DPD system 600 according to some embodiments. It will be appreciated that the DPD system 600 may be configured to perform the method as described with reference to FIGS. 2 to 5.

The DPD system 600 comprises a linearization bands configuration block 601. The linearization bands configuration block 601 may be configured to perform steps 201 to 203 as described with reference to FIG. 2.

The linearization bands configuration block will be described in more detail with reference to FIGS. 7 and 8.

The linearization bands configuration block 601 outputs adjusted MCB signals

$${u}_{1}^{′}$$

to u′_{N}.

The bands occupied by the adjusted MCB signals

$${u}_{1}^{′} to {u}_{N}^{′}$$

are frequency shifted to the linearization frequency bands. As will be described later with reference to FIGS. 6 and 7 (and as illustrated in the example shown in FIGS. 3 and 5).

The DPD system 600 then further comprises a plurality of S-DPDs 602₁ to 602_{N}. Each S-DPD receives the adjusted MCB signals u′₁ to u′_{N} as an input. Each S-DPD may be configured to perform step 204 As described with reference to FIG. 2. In particular, each S-DPD may perform digital predistortion on the input MCB signal, u′_{M} within the linearization frequency band centered on a respective second frequency F_{L,M} to generate a pre-distorted signal x_{M}.

The functionality of such an S-DPD may be provided without additional internal frequency shifts that are usually required to perform S-DPD, as the frequency shifting is performed outside of the S-DPD blocks. Each S-DPD may operate utilizing standard DPD techniques (see for example, W Cao., W. Cao, S. Wang and T. Eriksson, “Concurrent multiband linearization for power amplifiers with intermodulation distortions,” IEEE Microwave and Wireless Components Letters, vol. 32, no. 5, pp. 467-470, 2022)

Each S-DPD then outputs a pre-distorted MCB signal x₁ to x_{N}.

The pre-distorted MCB signals are then passed to the up-conversion blocks 603₁ to 603_{N}. The up-conversion blocks 603₁ to 603_{N} may each be configured to perform step 205 for one of the pre-distorted MCB signals x₁ to x_{N}.

For example, each up-conversion block 603₁ to 603_{N} may receive an indication of a respective shift factor δ_{M} from the linearization bands configuration block 601. Each up-conversion block may then be configured to perform step 205 as described with reference to FIG. 2 to generate the output MCB signals x_{UP,1} to x_{UP,N}.

The output MCB signals may then be combined and forwarded to a digital-to-analog convertor (DAC) before input into a PA.

The DPD system 600 therefore receives the MCB input signals (u₁, . . . , u_{N}) and translates them in frequency according to the proposed configuration of linearization bands (e.g. as illustrated in FIG. 5). These are then passed to the S-DPDs, which may then operate without any additional internal frequency shifts.

FIG. 7 illustrates an example implementation of a linearization bands configuration block 601 according to some embodiments.

In this example, the linearization bands configuration block 601 receives the following inputs:
a vector F_{C}=[F_{C,1},F_{C,2}, . . . , F_{C,N}] comprising the central frequencies of the MCB input signals,
a set of parameters P=[nor_sel, B_{L} . . . ] comprising at least a nor_sel parameter used to configure an optimizer module (as will be described in more detail with reference to FIG. 8), and optionally comprising B_{L}=[B_{L,1}, B_{L,2}, . . . , B_{L,N}] comprising the bandwidths of each MCB input signal;
a vector δ_{I}=[δ_{I,1}, δ_{I,2}, . . . , δ_{I,N}] comprising the values of shift factors to be used when the linearization bands configuration block operates in “manual configuration mode”.
a mode-selection signal s, that may be, for example, a binary signal that selects the operational mode of the linearization bands configuration block in either “automatic configuration mode” or “manual configuration mode”.

When operating in the “automatic configuration mode”, which as described above may be indicated by the mode-selection signal, s, the shift vector δ is taken as the output of the optimizer block, i.e., δ_{O}=[δ_{O,1}, δ_{O,2}, . . . , δ_{O,N}]. The optimizer block 700 will be described in more detail with reference to FIG. 8.

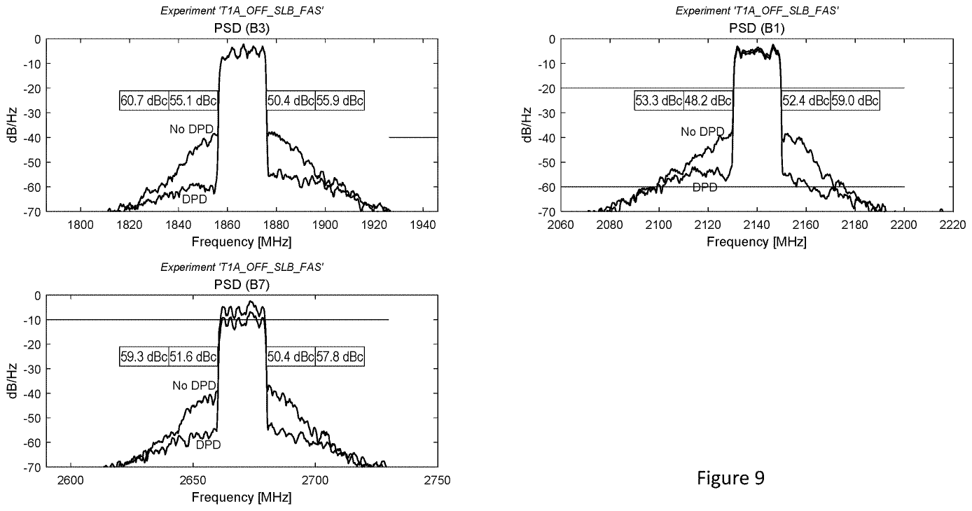

When operating in “manual mode” (which, as described above, may be indicated by the mode-selection signal, s) the shift vector δ is taken as the manual shift vector δ_{I}=[δ_{I,1}, δ_{I,2}, . . . , δ_{I,N}]. It will be appreciated that a user may manually select 8, to obtain the proposed configuration of linearization bands (e.g. as illustrated in FIG. 5) for the predistortion scheme to give the frequency shift reduction advantages as will be described later with reference to FIGS. 9 to 11.

It will be appreciated that regardless of the mode of operation, the shift vector δ may be output by the linearization bands configuration block 601 for use in the up-conversion blocks 603₁ to 603_{N}, for example, as described with reference to FIG. 6. Irrespective of the approach used for generating the multiband signal (e.g. in digital- or analog-domain, in other words, before or after the DAC), the mixing block may comprise a compensation frequency-offset to each of the MCB pre-distorted signals when generating the output MCB signal.

The linearization bands configuration block 601 then further comprises frequency shifters 701₁ to 701_{N}. These frequency shifters 701₁ to 701_{N} receive respective shift factors that form elements of the shift vector δ and the input MCB signals u₁ to u_{N}.

Each frequency shifter 701_{M} shifts the frequency of the respective MCB input signal by the respective shift factor δ_{M} to generate the adjusted MCB signal u_{M}. In other words, each frequency shifter 701_{M} may be considered to be configured to perform step 203 of FIG. 2. As illustrated in FIG. 6, each adjusted MCB signal u′_{M} may then be used as an input to each S-DPD 602₁ to 602_{N} FIG. 8 illustrates an example implementation of the optimiser block 700.

The optimizer block 700 is configured to generate the frequency shift vector δ_{O}=[δ_{0,1}, δ_{0,2}, . . . , δ_{0,N}].

It will be appreciated that the frequency shift vector may in some examples only be utilized when the linearization bands configuration block 601 is in an “automatic configuration mode”.

The optimizer block 700 may then provide δ_{O} as an output to the frequency shifters 701₁ to 701_{N} and the up-conversion blocks 603₁ to 603_{N}.

The optimizer block 700 may receive as an input:
a vector of the set of first frequencies F_{C}=[F_{C,1}, F_{C,2}, . . . , F_{C,N}]
the set of parameters P=[nor_sel,B_{L} . . . ] comprising at least a nor_sel parameter used to configure an optimizer module (as will be described in more detail with reference to FIG. 8), and optionally comprising B_{L}=[B_{L,1}, B_{L,2}, . . . , B_{L,N}] comprising the bandwidths of each MCB input signal; and/or other arbitrary parameters.

A determining module 800 may then be configured to determine the set of second frequencies F_{L}=[F_{L,1}, F_{L,2}, . . . , F_{L,N}] that represent the center frequencies of the linearization bands.

Determining module 800 may be configured to perform step 202 as described with reference to FIG. 2.

It will be appreciated that the set of second frequencies F_{L} may be obtained via a constrained minimization of the L^{nor_sel}-norm of the vector F_{C}−F_{L}. In other words, step 202 of FIG. 2 may be subject to some constraints.

The constraints of the optimization problem may be arbitrarily configured in a constraints setting module 801. For example, the constraints setting module 801 may be used to force a range of the output set of second frequencies F_{L} within a range of feasible/desired values for a specific architecture and/or linearization task. Those scenario-depended parameters may be passed to the constraints setting module 801 via the set of parameters P.

### Experimental Results

The performance of a system such as described with reference to FIGS. 6 to 8 (herein referred to as a proposed solution) has been tested and its performance and complexity compared to a legacy S-DPD setup with standard linearization bands settings, both with and without additional NCO to linearize off-centered IMs.

The simulation-based test parameters are given in the following table:

TABLE 1
Simulation parameters.

| Parameter | Value |
|---|---|
| Number of concurrent bands | 3 |
| Band/Carrier frequency | B3/1866 MHz, B1/2140 MHz, |
| | B7/2670 MHz |
| MCB signal/channel bandwidth | 18 MHz / 20 MHz |
| Required linearization bands shift | 0 MHz, 6 MHz, 0 MHz |
| (proposed solution) | |
| S-DPD model | Memoryless polynomial |
| S-DPD model nonlinearity order | 7 |
| S-DPD model memory depth | 0 |
| Linearization bandwidth (per S-DPD) | 122.88 MHz |
| Simulated PA model | Memory Polynomial |
| Simulated PA model, nonlinear order | 8 |
| Simulated PA model, memory depth order | 7 |

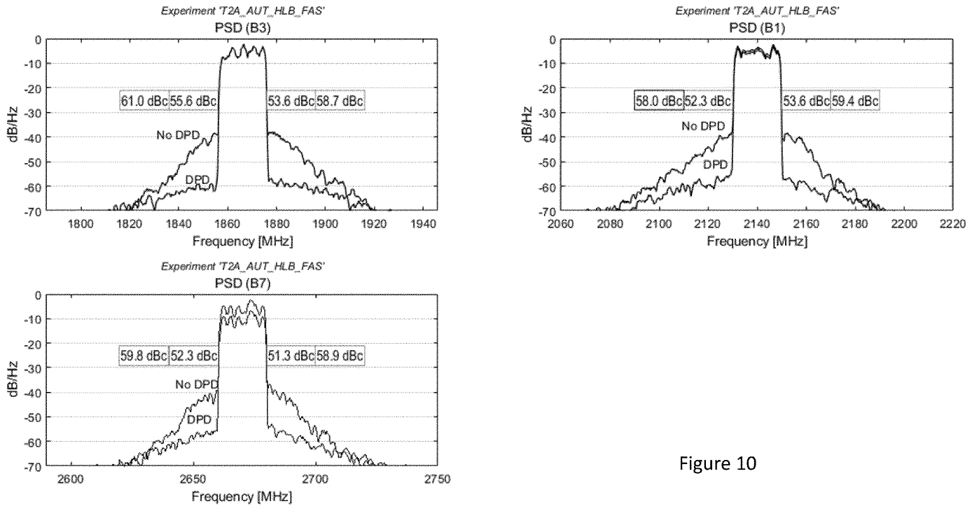

The results on linearization performance are shown in FIG. 9 and FIG. 10.

FIG. 9 illustrates the spectrum of signals with and without S-DPD for the standard linearization bands (SLB) case. The linearization performance is quantified in the figure in terms of alternate channels leakage ratio (external values) and adjacent channels leakage ratio (internal values). Each graph shows the spectrum of signal in one of the three 3GPP frequency bands that are linearized, that is, band 3 (B3), band 1 (B1), and band 7 (B7).

FIG. 10 illustrates the spectrum of signals with and without S-DPD for the proposed solution. The linearization performance is quantified in the figure in terms of alternate channels leakage ratio (external values) and adjacent channels leakage ratio (internal values). Each graph shows the spectrum of signal in one of the three 3GPP frequency bands that are linearized, that is, band 3 (B3), band 1 (1), and band 7 (B7).

The simulations show that linearization of off-centered IM terms in the proposed solution according to embodiments described herein reduces the adjacent channel leakage ratio (ACLR) especially for 1 and B3 when compared to the standard linearization bands (SLB) case.

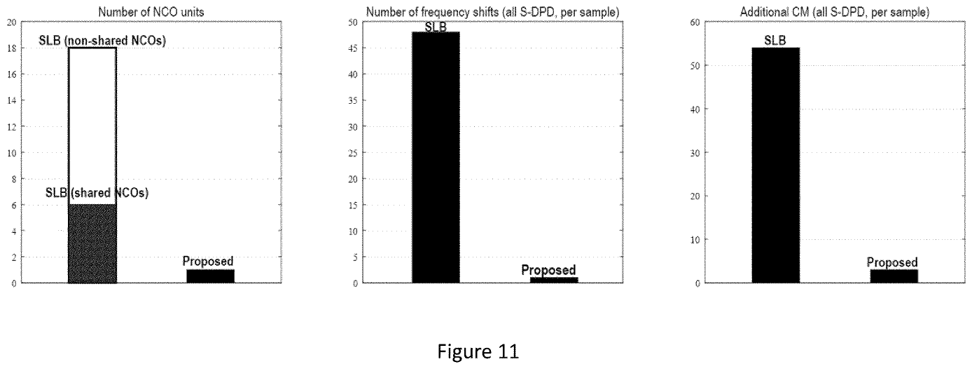

FIG. 11 illustrates the complexity of S-DPD in terms of frequency shifts (in this case NCO), number of frequency shifts and complex multiplications (CM) related to the additional frequency shifts in different scenarios: standard linearization bands (SLB), and the proposed solution.

The first scenario covers standard linearization bands (SLB) where off-centered IMs are linearized via ad-hoc NCOs. The last scenario is the proposed solution, which shows significant reduction of all the selected complexity metrics compared to both reference scenarios. The reduction with respect to the SLB scenario is motivated by the fact that in the proposed solution there are no IM-related NCO, but only one NCO is needed as shown in Table 1, even while retaining the same linearization performance.

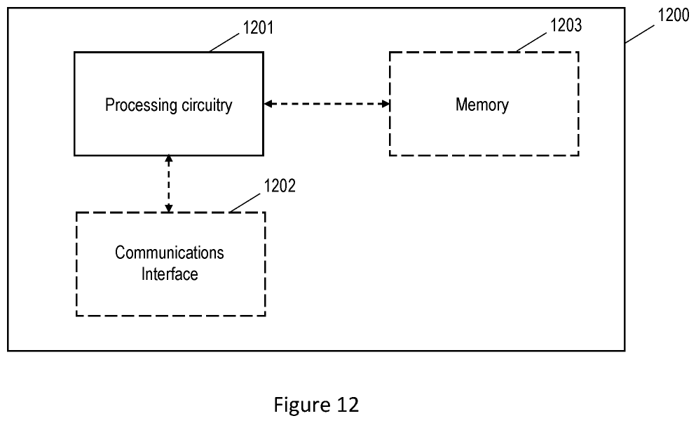

FIG. 12 illustrates an apparatus 1200 comprising processing circuitry (or logic) 1201. The processing circuitry 1201 controls the operation of the apparatus 1200 and can implement the method described herein in relation to an apparatus 1200. The processing circuitry 1201 can comprise one or more processors, processing units, multi-core processors or modules that are configured or programmed to control the apparatus 1200 in the manner described herein. In particular implementations, the processing circuitry 1201 can comprise a plurality of software and/or hardware modules that are each configured to perform, or are for performing, individual or multiple steps of the method described herein in relation to the apparatus 1200. It will be appreciated that the apparatus 1200 may comprise one or more virtual machines running different software and/or processes. The apparatus 1200 may therefore comprise, or be implemented in or as one or more servers, switches and/or storage devices and/or may comprise cloud computing infrastructure that runs the software and/or processes.

Briefly, the processing circuitry 1201 of the apparatus 1200 is configured to: obtain an indication of a set of first frequencies (F_{C,1} to F_{C,N}) comprising central frequencies of the plurality of initial frequency bands; determine a set of second frequencies (F_{L,1} to F_{L,N}), wherein each second frequency F_{L} equals a respective first integer value (m₁ to M_{N}) multiplied by a frequency interval (Δf), wherein the frequency interval equals a highest second frequency (F_{L,N}) in the set of second frequencies divided by a second integer value, R; for each input MCB signal, u_{M}: frequency shift the input MCB signal, u_{M} into a linearization frequency band centered on a respective second frequency F_{L,M} to generate an adjusted input MCB signal u′_{M}; perform digital predistortion on the adjusted input MCB signal, u′_{M} to generate a pre-distorted MCB signal, x_{M}; and upconvert the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

In some embodiments, the apparatus 1200 may optionally comprise a communications interface 1202. The communications interface 1202 of the apparatus 1200 can be for use in communicating with other nodes, such as other virtual nodes. For example, the communications interface 1202 of the apparatus 1200 can be configured to transmit to and/or receive from other nodes requests, resources, information, data, signals, or similar. The processing circuitry 1201 of apparatus 1200 may be configured to control the communications interface 1202 of the apparatus 1200 to transmit to and/or receive from other nodes requests, resources, information, data, signals, or similar. The communications interface 1202 can use any suitable communication technology.

Optionally, the apparatus 1200 may comprise a memory 1203. In some embodiments, the memory 1203 of the apparatus 1200 can be configured to store program code that can be executed by the processing circuitry 1201 of the apparatus 1200 to perform the method described herein in relation to the apparatus 1200. Alternatively or in addition, the memory 1203 of the apparatus 1200, can be configured to store any requests, resources, information, data, signals, or similar that are described herein. The processing circuitry 1201 of the apparatus 1200 may be configured to control the memory 1203 of the apparatus 1200 to store any requests, resources, information, data, signals, or similar that are described herein. The apparatus 1200 may be configured operate in the manner described herein in respect of an apparatus.

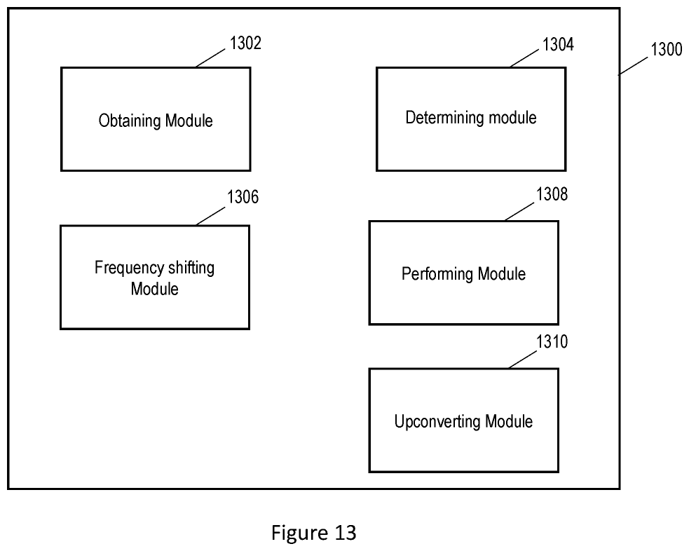

FIG. 13 is a block diagram illustrating an apparatus 1300 according to some embodiments. The apparatus 1300 can generate output MCB signals (x_{UP,1} to x_{UP,N}) for driving a power amplifier. The apparatus 1300 comprises a obtaining module 1302 configured to obtain an indication of a set of first frequencies (F_{C,1} to F_{C,N}) comprising central frequencies of the plurality of initial frequency bands. The apparatus 1300 comprises a determining module 1304 configured to determine a set of second frequencies (F_{L,1} to F_{L,N}), wherein each second frequency F_{L} equals a respective first integer value (m₁ to M_{N}) multiplied by a frequency interval (Δf), wherein the frequency interval equals a highest second frequency (F_{L,N}) in the set of second frequencies divided by a second integer value, R. The apparatus 1300 further comprises a frequency shifting module 1306 configured to, for each input MCB signal, u_{M}, frequency shift the input MCB signal, u_{M} into a linearization frequency band centered on a respective second frequency F_{L,M} to generate an adjusted input MCB signal u_{M}. The apparatus 1300 further comprises a performing module 1308 configured to, for each input MCB signal, perform digital predistortion on the adjusted input MCB signal, u′_{M} to generate a pre-distorted MCB signal, x_{M}. The apparatus 1300 further comprises a upconverting module 1310 configured to, for each input MCB signal, u_{M}, upconvert the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

The apparatus 1300 may operate in the manner described herein in respect of an apparatus.

There is also provided a computer program comprising instructions which, when executed by processing circuitry (such as the processing circuitry 1201 of the apparatus 1200 described earlier), cause the processing circuitry to perform at least part of the method described herein. There is provided a computer program product, embodied on a non-transitory machine-readable medium, comprising instructions which are executable by processing circuitry to cause the processing circuitry to perform at least part of the method described herein. There is provided a computer program product comprising a carrier containing instructions for causing processing circuitry to perform at least part of the method described herein. In some embodiments, the carrier can be any one of an electronic signal, an optical signal, an electromagnetic signal, an electrical signal, a radio signal, a microwave signal, or a computer-readable storage medium.

Embodiments described herein allow for linearizing IMs that are off-centered with the central frequency of a predistorted signal without using additional frequency shifters in the S-DPDs, which allows for decoupling the number of NCOs from the number of off-centered IMs minimizing both area and number of multiplications in the S-DPD.

Embodiments described herein also allow for using the same S-DPD nonlinear model for different combinations of bands, therefore improving reusability of the developed S-DPD solution in deployments.

Embodiments described herein also allow for relaxing requirements on frequency shifters external to the S-DPDs by allowing:
a. multiple configurations of the frequency shifters,
b. a lower amount of frequency shifters,
c. a lower magnitude of frequency shifts.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1.-14. (canceled)

15. A method for performing digital predistortion of a plurality of input multi-carrier branch (MCB) signals, u₁ to u_{N}, to generate output MCB signals, x_{UP,1} to x_{UP,N}, for driving a power amplifier, wherein each input MCB signal occupies a respective initial frequency band, the method comprising:
obtaining an indication of a set of first frequencies, F_{C,1} to F_{C,N}, comprising central frequencies of the plurality of initial frequency bands;
determining a set of second frequencies, F_{L,1} to F_{L,N}, wherein each second frequency F_{L} equals a respective first integer value, m₁ to M_{N}, multiplied by a frequency interval, Δf, wherein the frequency interval equals a highest second frequency, F_{L,N}, in the set of second frequencies divided by a second integer value, R;
for each input MCB signal, u_{M}:
frequency shifting the input MCB signal, u_{M} into a linearization frequency band centered on a respective second frequency F_{L,M} to generate an adjusted input MCB signal u′_{M};
performing digital predistortion on the adjusted input MCB signal, u′_{M} to generate a pre-distorted MCB signal, x_{M}; and
upconverting the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

16. The method of claim 15, wherein a shift vector δ, comprises a difference between a vector of the first set of frequencies, F_{C}=[F_{C,1}, . . . , F_{C,N}] and a vector of the second set of frequencies, F_{L}=[F_{L,1}, . . . , F_{L,N}].

17. The method of claim 16, wherein the step of determining the set of second frequencies, F_{L,1} to F_{L,N}, comprises:
selecting the second set of frequencies to reduce an L^{nor-sel} norm of the shift vector, where nor_sel is 0, ∞ or an integer value.

18. The method of claim 17 further comprising receiving the value of nor_sel for the L^{nor-sel} norm as an input.

19. The method of claim 16 wherein the step of determining the set of second frequencies comprises:
selecting one or more of the respective first integer values and the second integer value to produce the set of second frequencies to ensure a total number of intermodulation terms located at hypothetical carrier frequencies should the hypothetical carrier frequencies be set equal to the set of second frequencies reaches or surpasses a threshold value.

20. The method of claim 15 wherein, for each input MCB signal, the step of performing the digital predistortion on the adjusted MCB signal is performed in separate DPD blocks.

21. The method of claim 15 wherein to perform the upconverting of the pre-distorted signal, x_{M}, to generate the respective output MCB signal x_{UP,M} the output MCB signal x_{UP,M} is calculated as: x_{UP,M}=x_{M}e^{j2π(f}^{_{C,M}}^{-δ}^{_{M}}^{)t}.

22. The method of claim 15 further comprising receiving an indication of the shift vector as an input.

23. An apparatus for performing digital predistortion of a plurality of input multi-carrier branch (MCB) signals, u₁ to u_{N}, to generate output MCB signals, x_{UP,1} to x_{UP,N}, for driving a power amplifier, the apparatus comprising processing circuitry configured to cause the apparatus to:
obtain an indication of a set of first frequencies, F_{C,1} to F_{C,N}, comprising central frequencies of the plurality of initial frequency bands;
determine a set of second frequencies, F_{L,1} to F_{L,N}, wherein each second frequency F_{L} equals a respective first integer value, m₁ to M_{N}, multiplied by a frequency interval, Δf, wherein the frequency interval equals a highest second frequency, F_{L,N}, in the set of second frequencies divided by a second integer value, R;
for each input MCB signal, u_{M}:
frequency shift the input MCB signal, u_{M} into a linearization frequency band centered on a respective second frequency F_{L,M} to generate an adjusted input MCB signal u′_{M};
perform digital predistortion on the adjusted input MCB signal, u′_{M} to generate a pre-distorted MCB signal, x_{M}; and
upconvert the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.

24. The apparatus of claim 23, wherein a shift vector δ, comprises a difference between a vector of the first set of frequencies, F_{C}=[F_{C,1}, . . . , F_{C,N}] and a vector of the second set of frequencies, F_{L}=[F_{L,1}, . . . , F_{L,N}].

25. The apparatus of claim 24, wherein the processing circuitry is configured to determine the set of second frequencies, F_{L,1} to F_{L,N}, by:
selecting the second set of frequencies to reduce an L^{nor_sel} norm of the shift vector, where nor_sel is 0, ∞ or an integer value.

26. The apparatus of claim 25, wherein the processing circuitry is further configured to receive the value of nor_sel for the L^{nor_sel} norm as an input.

27. The apparatus of claim 24, wherein the processing circuitry is configured to determine the set of second frequencies by:
selecting one or more of the respective first integer values and the second integer value to produce the set of second frequencies to ensure a total number of intermodulation terms located at hypothetical carrier frequencies should the hypothetical carrier frequencies be set equal to the set of second frequencies reaches or surpasses a threshold value.

28. The apparatus of claim 23, wherein the processing circuitry is configured to, for each input MCB signal, perform the digital predistortion on the adjusted MCB signal is performed in separate DPD blocks.

29. The apparatus of claim 24, wherein the processing circuitry is configured to upconvert the pre-distorted signal, x_{M}, to generate the respective output MCB signal x_{UP,M} by calculating the output MCB signal x_{UP,M} as: x_{UP,M}(t)=x_{M}(t)e^{j2π(f}^{_{C,M}}^{-δ}^{_{M}}^{)t}.

30. The apparatus of claim 24, wherein the processing circuitry is further configured to receive an indication of the shift vector as an input.

31. A base station comprising the apparatus of claim 23.

32. A non transitory computer readable medium having stored thereon instructions that, when executed by a processor of an apparatus, cause the apparatus to perform digital predistortion of a plurality of input multi-carrier branch (MCB) signals, u₁ to u_{N}, to generate output MCB signals, x_{UP,1} to x_{UP,N}, for driving a power amplifier, wherein each input MCB signal occupies a respective initial frequency band, the instructions causing the apparatus to:
obtain an indication of a set of first frequencies, F_{C,1} to F_{C,N}, comprising central frequencies of the plurality of initial frequency bands;
determine a set of second frequencies, F_{L,1} to F_{L,N}, wherein each second frequency F_{L} equals a respective first integer value, m₁ to M_{N}, multiplied by a frequency interval, Δf, wherein the frequency interval equals a highest second frequency, F_{L,N}, in the set of second frequencies divided by a second integer value, R;
for each input MCB signal, u_{M}:
frequency shift the input MCB signal, u_{M} into a linearization frequency band centered on a respective second frequency F_{L,M} to generate an adjusted input MCB signal u′_{M};
perform digital predistortion on the adjusted input MCB signal, u′_{M} to generate a pre-distorted MCB signal, x_{M}; and
upconvert the pre-distorted signal, x_{M}, to generate a respective output MCB signal x_{UP,M} utilizing a respective target frequency, F_{D,M} that is adjusted by a shift factor, δ_{M}, wherein the shift factor δ_{M} comprises a difference between a respective first frequency F_{C,M} and the respective second frequency F_{L,M}.
